(19) United States
(12) Patent Application Publication
(10) Pub. No.: US 2017/0033107 A1
(43) Pub. Date: Feb. 2, 2017

(54) SEMICONDUCTOR DEVICE AND METHOD FOR MANUFACTURING THE SAME

(71) Applicant: Samsung Electronics Co., Ltd., Suwon-si (KR)

(72) Inventors: Byoung Hak HONG, Seoul (KR); Sungil Park, Suwon-si (KR); Toshinori Fukai, Suwon-si (KR); Shigenobu Maeda, Seongnam-si (KR); Sada-aki Masuoka, Seongnam-si (KR); Sanghyun Lee, Anyang-si (KR); Keon Yong Cheon, Yongin-si (KR); Hock-Chun Chin, Hwaseong-si (KR)

(73) Assignee: Samsung Electronics Co., Ltd., Suwon-si (KR)

(21) Appl. No.: 15/159,978

(22) Filed: May 20, 2016

(30) Foreign Application Priority Data
Jul. 30, 2015 (KR) 10-2015-0108158

(51) Int. Cl. H01L 27/092; H01L 21/265; H01L 21/8234; H01L 21/02; H01L 29/06; H01L 29/78

(52) U.S. Cl. CPC H01L 27/0924; H01L 29/0649; H01L 29/7846; H01L 21/823431; H01L 21/823418; H01L 21/02636; H01L 29/7848; H01L 21/02532; H01L 21/26513

(57) ABSTRACT

A semiconductor device includes a substrate including at least one metal-oxide-semiconductor field-effect transistor (MOSFET) region defined by a device isolation layer and having an active pattern extending in a first direction on the MOSFET region, a gate electrode intersecting the active pattern on the substrate and extending in a second direction intersecting the first direction, and a first gate separation pattern adjacent to the MOSFET region when viewed from a plan view and dividing the gate electrode into segments spaced apart from each other in the second direction. The first gate separation pattern has a tensile strain when the MOSFET region is a P-channel. MOSFET (PMOSFET) region. The first gate separation pattern has a compressive strain when the MOSFET region is an N-channel MOSFET (NMOSFET) region.

### CROSS-REFERENCE TO RELATED APPLICATION

This U.S. non-provisional patent application claims priority under 35 U.S.C. §119 to Korean Patent Application No. 10-2015-0108158, filed on Jul. 30, 2015, in the Korean Intellectual Property Office, the disclosure of which is hereby incorporated by reference in its entirety.

### BACKGROUND

1. Field

Some example embodiments of the inventive concepts relate to a semiconductor devices and a method for manufacturing the same, and more particularly, to a semiconductor device including a field effect transistor and a method for manufacturing the same.

2. Description of the Related Art

Semiconductor devices are widely used in an electronic industry because of their relatively small sizes, multi-functional characteristics and/or relatively low manufacturing costs. Semiconductor devices may be classified into semiconductor memory devices storing logical data, semiconductor logic devices processing logical data, and hybrid semiconductor devices having both the function of the semiconductor memory devices and the function of the semiconductor logic devices. Semiconductor devices with improved characteristics have been demanded with the development of the electronic industry. For example, relatively high-reliable, high-speed and/or multi-functional semiconductor devices have been increasingly demanded. To satisfy these demands, structures of semiconductor devices have been complicated and semiconductor devices have been highly integrated.

### SUMMARY

Some example embodiments of the inventive concepts may provide a semiconductor device including a field effect transistor with improved electrical characteristics.

Other example embodiments of the inventive concepts may provide a method for manufacturing a semiconductor device including a field effect transistor with improved electrical characteristics.

According to an example embodiment, a semiconductor device includes a substrate including at least one metal-oxide-semiconductor field-effect transistor (MOSFET) region defined by a device isolation layer and having an active pattern extending in a first direction on the MOSFET region, a gate electrode intersecting the active pattern on the substrate and extending in a second direction intersecting the first direction, and a first gate separation pattern adjacent to the MOSFET region when viewed from a plan view. The first gate separation pattern may divide the gate electrode into segments spaced apart from each other in the second direction. The first gate separation pattern may have one of a tensile strain and a compressive strain when the MOSFET region is one of a P-channel MOSFET (PMOSFET) region and N-channel MOSFET (NMOSFET) region, respectively.

In an example embodiment, the MOSFET region may be the PMOSFET region, and the active pattern may have a compressive strain.

In an example embodiment, the MOSFET region may be the NMOSFET region, and the active pattern may have a tensile strain.

In an example embodiment, a bottom surface of the first gate separation pattern may be at a lower level than a bottom surface of the gate electrode.

In an example embodiment, the first gate separation pattern may be on the device isolation layer, and a bottom surface of the first gate separation pattern may be at a lower level than a topmost surface of the device isolation layer.

In an example embodiment, a top surface of the first gate separation pattern may be at the same level as a top surface of the gate electrode.

In an example embodiment, the first gate separation pattern may extend in the first direction.

In an example embodiment, the semiconductor device may further include a second gate separation pattern dividing the gate electrode into segments spaced apart from each other in the second direction. The first and second gate separation patterns may be spaced apart from each other with the MOSFET region therebetween and the second gate separation pattern may be adjacent to the MOSFET region when viewed from a plan view. The second gate separation pattern may have a tensile strain when the MOSFET region is the PMOSFET region, and the second gate separation pattern may have a compressive strain when the MOSFET region is the NMOSFET region.

In an example embodiment, the MOSFET region may include a first MOSFET region and a second MOSFET region spaced apart from each other in the second direction. The first MOSFET region may correspond to the PMOSFET region and the second MOSFET region may correspond to the NMOSFET region. The first gate separation pattern may be adjacent to the first MOSFET region and the second gate separation pattern may be adjacent to the second MOSFET region. In this case, the first gate separation pattern may have the tensile strain and the second gate separation pattern may have the compressive strain.

In an example embodiment, the device isolation layer may extend between the first MOSFET region and the second MOSFET region, and the semiconductor device may further include a third gate separation pattern on the device isolation layer between the first MOSFET region and the second MOSFET region.

In an example embodiment, a distance between the third gate separation pattern and the first MOSFET region may be less than a distance between the third gate separation pattern and the second MOSFET region, and the third gate separation pattern may have a tensile strain.

In an example embodiment, a distance between the third gate separation pattern and the second MOSFET region may be less than a distance between the third gate separation pattern and the first MOSFET region, and the third gate separation pattern may have a compressive strain.

According to another example embodiment, a semiconductor device includes a substrate including an active pattern extending in a first direction, a gate electrode intersecting the active pattern on the substrate and extending in a second direction intersecting the first direction, source/drain regions on the active pattern at both sides of the gate electrode, and a gate separation pattern adjacent to the active pattern when viewed from a plan view. The gate separation pattern may divide the gate electrode into segments spaced apart from each other in the second direction. One of the active pattern and the gate separation pattern may have a tensile strain, and the other of the active pattern and the gate separation pattern may have a compressive strain.

In another example embodiment, the source/drain regions may include P-type dopants, the active pattern may have the compressive strain, and the gate separation pattern may have the tensile strain.

In another example embodiment, the source/drain regions may include N-type dopants, the active pattern may have the tensile strain, and the gate separation pattern may have the compressive strain.

According to another example embodiment, a semiconductor device includes a substrate including at least one active pattern, a gate electrode pattern intersecting the active pattern on the substrate, and an insulating pattern intersecting the gate electrode pattern and adjacent to the active pattern when viewed from a plan view, one of the active pattern and the insulating pattern has a compressive strain and the other of the active pattern and the insulating pattern having a tensile strain.

In another example embodiment, the active pattern may have the compressive strain, and the insulating pattern may include silicon oxide (SiO₂) and may have the tensile strain.

In another example embodiment, the semiconductor device may further include source/drain regions on the active pattern at both sides of the gate electrode pattern, the source/drain regions including P-type dopants.

In another example embodiment, the active pattern may have the tensile strain, and the insulating pattern may include silicon nitride (SiN) and may have the compressive strain.

In another example embodiment, the semiconductor device may further include source/drain regions on the active pattern at both sides of the gate electrode pattern, the source/drain regions including N-type dopants.

### BRIEF DESCRIPTION OF THE DRAWINGS

The inventive concepts will become more apparent in view of the attached drawings and accompanying detailed description.

FIG. 1 is a plan view illustrating a semiconductor device according to some example embodiments of the inventive concepts.

FIGS. 2A, 2B, and 2C are cross-sectional views taken along lines I-I′, II-II′, and III-III′ of FIG. 1, respectively.

FIGS. 3A, 5A, 6A, 7A, 8A, 9A and 10A are cross-sectional views corresponding to the line I-I′ of FIG. 1 to illustrate a method for manufacturing a semiconductor device according to some example embodiments of the inventive concepts.

FIGS. 3B, 5B, 6B, 7B, 8B, 9B and 10B are cross-sectional views corresponding to the line II-II′ of FIG. 1 to illustrate a method for manufacturing a semiconductor device according to some example embodiments of the inventive concepts.

FIGS. 3C, 5C, 6C, 7C, 8C, 9C and 10C are cross-sectional views corresponding to the line III-III′ of FIG. 1 to illustrate a method for manufacturing a semiconductor device according to some example embodiments of the inventive concepts.

FIGS. 4A to 4C are cross-sectional views taken along lines I-I′, II-II′, and III-III′ of FIG. 4D, respectively, and FIG. 4D is a plan view illustrating a shape of a sacrificial pattern to illustrate a method for manufacturing a semiconductor device according to some example embodiments of the inventive concepts.

FIG. 11 is a plan view illustrating a semiconductor device according to some example embodiments of the inventive concepts.

FIG. 12 is a plan view illustrating a semiconductor device according to some example embodiments of the inventive concepts.

FIGS. 13A and 13B are cross-sectional views taken along lines II-II′ and III-III′ of FIG. 12, respectively.

FIG. 14 is a plan view illustrating a semiconductor device according to some example embodiments of the inventive concepts.

FIGS. 15A and 15B are cross-sectional views taken along lines II-II′ and III-III′ of FIG. 14, respectively.

### DETAILED DESCRIPTION

The inventive concepts will now be described more fully hereinafter with reference to the accompanying drawings, in which example embodiments of the inventive concepts are shown. The advantages and features of the inventive concepts and methods of achieving them will be apparent from the following example embodiments that will be described in more detail with reference to the accompanying drawings. It should be noted, however, that the inventive concepts are not limited to the following example embodiments, and may be implemented in various forms. Accordingly, the example embodiments are provided only to disclose the inventive concepts and let those skilled in the art know the category of the inventive concepts. In the drawings, example embodiments of the inventive concepts are not limited to the specific examples provided herein and are exaggerated for clarity. The same reference numerals or the same reference designators denote the same elements throughout the specification.

As used herein, the singular terms “a,” “an” and “the” are intended to include the plural forms as well, unless the context clearly indicates otherwise. As used herein, the term “and/or” includes any and all combinations of one or more of the associated listed items. Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof. It will be also understood that although the terms first, second, third etc. may be used herein to describe various elements, these elements should not be limited by these terms. These terms are only used to distinguish one element from another element.

Additionally, example embodiments are described herein with reference to cross-sectional views and/or plan views that are idealized example views. Accordingly, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

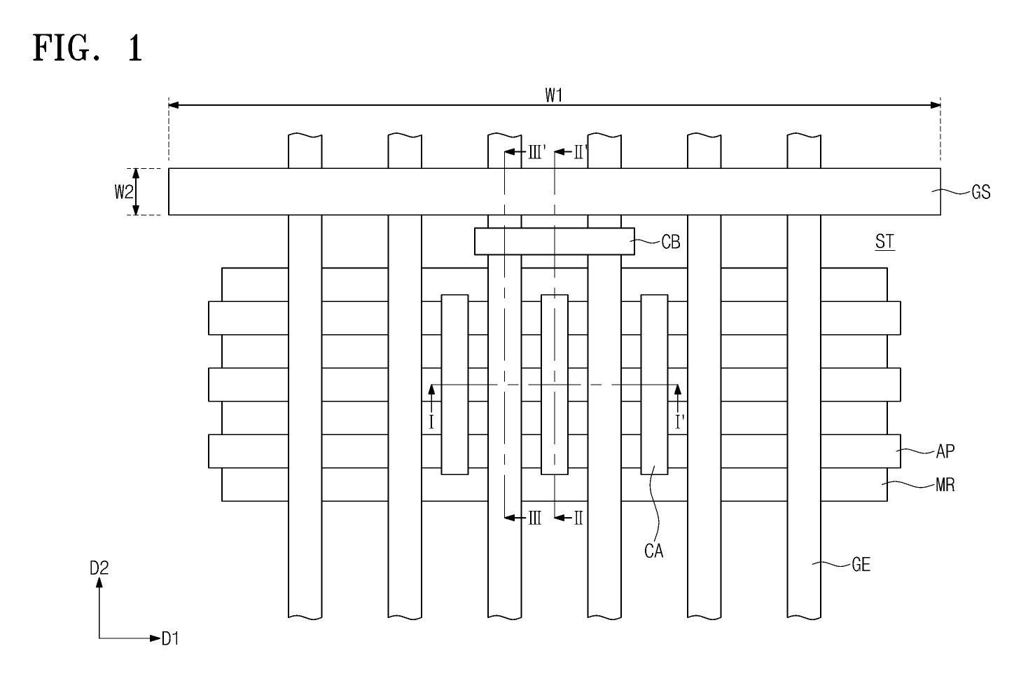

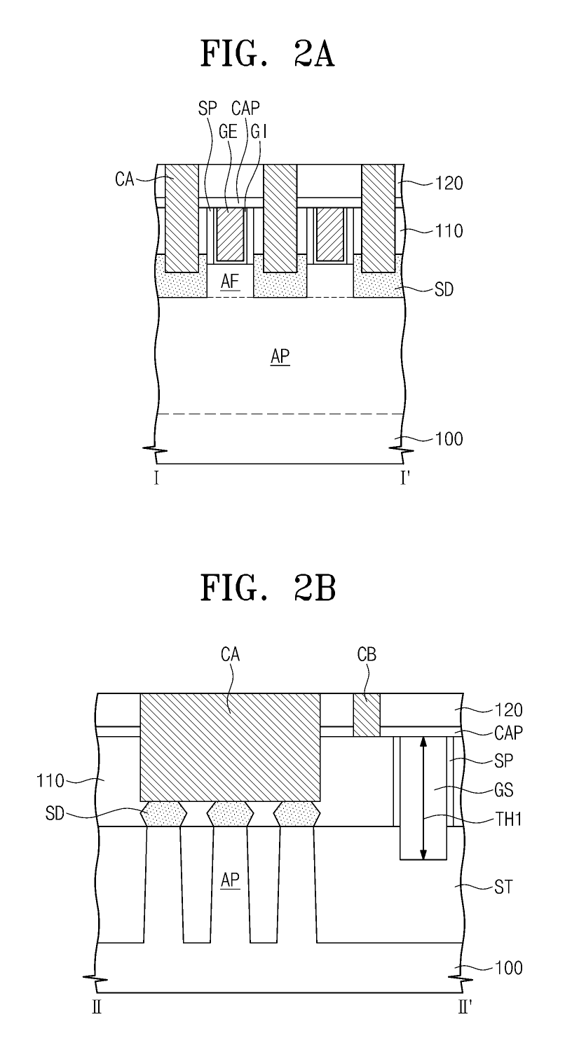

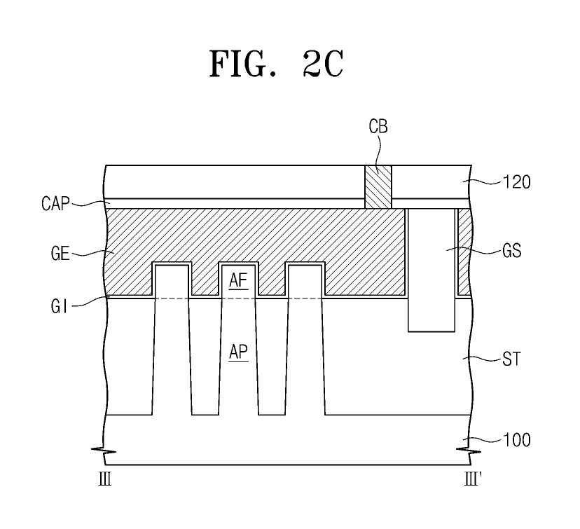

FIG. 1 is a plan view illustrating a semiconductor device according to some example embodiments of the inventive concepts. FIGS. 2A, 2B, and 2C are cross-sectional views taken along lines I-I′, II-II′, and III-II′ of FIG. 1, respectively.

Referring to FIGS. 1, 2A, 2B, and 2C, a device isolation layer ST may be disposed in a substrate 100 to define a metal-oxide-semiconductor field effect transistor (MOSFET) region MR of the substrate 100. For example, the substrate 100 may be a silicon substrate, a germanium substrate, or a silicon-on-insulator (SOI) substrate. The device isolation layer ST may include, for example, silicon oxide. The MOSFET region MR may be a P-channel MOSFET (PMOSFET) region on which a PMOSFET is formed, or an N-channel MOSFET (NMOSFET) region on which an NMOSFET is formed.

The substrate 100 may include active patterns AP extending in a first direction D1 thereon. The active patterns AP may be arranged in a second direction D2 intersecting (e.g., perpendicular to) the first direction D1. According to some example embodiments, the device isolation layer ST may extend between the active patterns AP.

According to some example embodiments, each of the active patterns AP may include an upper portion (hereinafter, referred to as ‘an active fin AF’) exposed by the device isolation layer ST. In other words, levels of top surfaces of the active patterns AP may be higher than a level of a top surface of the device isolation layer ST. However, some example embodiments of the inventive concepts are not limited thereto. In some example embodiments, the top surfaces of the active patterns AP may be substantially coplanar with the top surface of the device isolation layer ST.

The active patterns AP (e.g., the active fins AF) may have a strain. If the MOSFET region MR is the PMOSFET region, the active patterns AP may have a compressive strain. If the MOSFET region MR is the NMOSFET region, the active patterns AP may have a tensile strain. The strain of the active patterns AP will be described later in more detail when a gate separation pattern (GS) and source/drain regions SD is described.

The active patterns AP may be provided on the MOSFET region MR. In FIG. 1, three active patterns AP are provided on the MOSFET region MR. However, some example embodiments of the inventive concepts are not limited thereto.

Gate electrodes GE may be provided on the active patterns AP to intersect the active patterns AP. Each of the gate electrodes GE may extend in the second direction D2 to intersect the MOSFET region MR. The gate electrodes GE may be arranged along the first direction D1. The gate electrodes GE may include at least one of a doped semiconductor material, a metal, or a conductive metal nitride.

The gate electrodes GE may include impurities such as oxygen (O) or fluorine (F). The impurities may be diffused or permeated from surfaces of the gate electrodes GE. Diffusion degree of the impurities may be affected by a strain applied to the gate electrodes GE. In some example embodiments, the diffusion of the impurities may be inhibited when a compressive strain is applied to the gate electrodes GE, and thus, the gate electrodes GE may have a relatively low impurity concentration. In other example embodiments, the diffusion of the impurities may be relatively easy when a tensile strain is applied to the gate electrodes GE, and thus, the gate electrodes GE may have a relatively high impurity concentration.

A gate separation pattern GS may be provided to divide at least one of the gate electrodes GE into segments spaced apart from each other in the second direction D2. The segments may correspond to portions of the gate electrode GE. According to some example embodiments, as illustrated in FIG. 1, the gate separation pattern GS may extend in the first direction D1 to divide each of a plurality of gate electrodes GE into segments spaced apart from each other in the second direction D2. Alternatively, the gate separation pattern GS may divide only one gate electrode GE into segments spaced apart from each other in the semiconductor device D2. The gate separation pattern GS may include an insulating material. For example, the gate separation pattern GS may include at least one of silicon oxide, silicon nitride, or silicon oxynitride.

The gate separation pattern GS may be adjacent to the MOSFET region MR but may not overlap with the MOSFET region MR when viewed from a plan view. The gate separation pattern GS may be spaced apart from the MOSFET region MR in the second direction D2 when viewed from a plan view.

The gate separation pattern GS may be disposed on the device isolation layer ST. According to some example embodiments, a lower portion of the gate separation pattern GS may be inserted into the device isolation layer ST. In an example embodiment, a bottom surface of the gate separation pattern GS may be disposed at a lower level than the topmost surface of the device isolation layer ST. In an example embodiment, the bottom surface of the gate separation pattern GS may be disposed at a lower level than bottom surfaces of the gate electrodes GE. A top surface of the gate separation pattern GS may be disposed at the same level as top surfaces of the gate electrodes GE.

The gate separation pattern GS may have a strain. Due to the gate separation pattern GS, a strain may be applied to other elements adjacent to the gate separation pattern GS. For example, the gate separation pattern GS may apply a strain to the gate electrodes GE and the active patterns AP adjacent thereto.

When the MOSFET region MR is the PMOSFET region, the gate separation pattern GS may have a tensile strain. In this case, the gate separation pattern GS may apply a compressive strain to other elements adjacent to the gate separation pattern GS, and thus the other elements adjacent to the gate separation pattern GS may have the compressive strain. For example, the gate electrodes GE and the active patterns AP adjacent to the gate separation pattern GS may have the compressive strain.

When the MOSFET region MR is the NMOSFET region, the gate separation pattern GS may have a compressive strain. In this case, the gate separation pattern GS may apply a tensile strain to other elements adjacent to the gate separation pattern GS, and thus the other elements adjacent to the gate separation pattern GS may have the tensile strain. For example, the gate electrodes GE and the active patterns AP adjacent to the gate separation pattern GS may have the tensile strain.

An influence (e.g., the strain) of the gate separation pattern GS on the adjacent other elements may be varied depending on a magnitude of the strain of the gate separation pattern GS. For example, the magnitude of the strain applied to the gate electrodes GE and the active patterns AP by the gate separation pattern GS may increase as the magnitude of the strain of the gate separation pattern GS increases.

The influence (e.g., the strain) of the gate separation pattern GS on the other adjacent elements may decrease as a distance from the gate separation pattern GS increases. For example, the magnitude of the strain applied to the gate electrodes GE and the active patterns AP by the gate separation pattern GS may decrease as a distance from the gate separation pattern GS increases.

The influence (e.g., the strain) of the gate separation pattern GS on the other adjacent elements may be varied depending on a shape of the gate separation pattern GS. For example, the magnitude of the strain applied to the gate electrodes GE and the active patterns AP by the gate separation pattern GS may increase in proportion to a thickness TH1 of the gate separation pattern GS in a direction perpendicular to the substrate 100, a width W1 in the first direction D1 of the gate separation pattern GS, and a width W2 in the second direction D2 of the gate separation pattern GS.

A gate insulating pattern GI may be provided under each of the gate electrodes GE. The gate insulating pattern GI may be disposed between the gate electrode GE and the active pattern AP, and between the gate electrode GE and the device isolation layer ST. According to some example embodiments, the gate insulating pattern GI may further extend between the gate electrode GE and a sidewall of the gate separation pattern GS. According to some example embodiments, the gate insulating pattern GI may further extend between the gate electrode GE and spacers SP to be described later. The gate insulating pattern GI may include at least one of a silicon oxide layer, a silicon oxynitride layer, or a high-k dielectric layer having a higher dielectric constant than silicon oxide.

A capping pattern CAP may be provided on the gate electrodes GE. The capping pattern CAP may include at least one of silicon oxide, silicon nitride, or silicon oxynitride.

Spacers SP may be provided on both sidewalls of each of the gate electrodes GE. According to some example embodiments, as illustrated in FIG. 2B, the spacer SP may also be provided between the gate separation pattern GS and a first interlayer insulating layer 110 to be described later. Alternatively, the spacer SP may not be provided between the gate separation pattern GS and the first interlayer insulating layer 110. For example, the spacers SP may include at least one of silicon oxide, silicon nitride, or silicon oxynitride.

Source/drain regions SD may be provided on the active patterns AP at both sides of each of the gate electrodes GE. According to some embodiments, as illustrated in FIGS. 2A and 2B, the source/drain regions SD may include epitaxial patterns grown using the active patterns AP as a seed. When the MOSFET region MR is the PMOSFET region, the source/drain regions SD may be formed to apply a compressive strain to the active patterns AP (or the active fins AF) disposed under the gate electrodes GE. For example, the source/drain regions SD may include silicon-germanium (SiGe) doped with P-type dopants. When the MOSFET region MR is the NMOSFET region, the source/drain regions SD may be formed to apply a tensile strain to the active patterns AP (or the active fins AF) disposed under the gate electrodes GE. For example, the source/drain regions SD may include silicon carbide (SiC) doped with N-type dopants. In some example embodiments, when the MOSFET region MR is the NMOSFET region, the source/drain regions SD may include silicon doped with N-type dopants.

Unlike FIGS. 2A and 2B, source/drain regions SD may be dopant regions provided in the active patterns AP at both sides of each of the gate electrodes GE. When the MOSFET region MR is the PMOSFET region, the source/drain regions SD may be P-type dopant regions. When the MOSFET region MR is the NMOSFET region, the source/drain regions SD may be N-type dopant regions.

Portions (e.g., the active fins AF) of the active patterns AP, which are disposed under each of the gate electrodes GE and overlapped with the gate electrodes GE, may be used as channel regions.

A first interlayer insulating layer 110 may be provided on the substrate 110 to cover the gate electrodes GE and the source/drain regions SD. According to an example embodiment, the first interlayer insulating layer 110 may be provided between the substrate 100 and the capping pattern CAP. The first interlayer insulating layer 110 may include at least one of silicon oxide or silicon oxynitride.

A second interlayer insulating layer 120 may be provided on the capping pattern CAP. The second interlayer insulating layer 120 may include at least one of silicon oxide or silicon oxynitride.

First contacts CA may be provided between the gate electrodes GE. The first contacts CA may penetrate the second interlayer insulating layer 120, the capping pattern CAP, and the first interlayer insulating layer 110 so as to be connected to the source/drain regions SD. According to some example embodiments, as illustrated in FIGS. 1 and 2B, each of the first contacts CA may extend in the second direction D2 so as to be connected to a plurality of the source/drain regions SD. However, some example embodiments of the inventive concepts are not limited to thereto, and the number of the source/drain regions SD connected to each of the first contacts CA may be varied. The first contacts CA, for example, may include at least one of a doped semiconductor material, a metal, or a conductive metal nitride.

A second contact CB may penetrate the second interlayer insulating layer 120 and the capping pattern CAP so as to be electrically connected to the gate electrodes GE. According to some embodiments, as illustrated in FIG. 1, the second contact CB may extend in the first direction D1 so as to be connected to a plurality of the gate electrodes GE. However, some example embodiments of the inventive concepts are not limited to thereto, and the number of the gate electrodes GE connected to the second contact CB may be varied. The second contact CB may include the same material as the first contact CA. For example, the second contact CB may include at least one of a doped semiconductor material, a metal, or a conductive metal nitride.

Interconnections (not shown) may be provided on the substrate 100 so as to be electrically connected to the first contacts CA and the second contact CB. Operating voltages may be applied to the source/drain regions SD and the gate electrodes GE through the interconnections.

According to some example embodiments of the inventive concepts, the gate separation pattern GS may have strain. In the case in which the MOSFET region MR is the PMOSFET region, the gate separation pattern GS may have the tensile strain, and thus the compressive strain may be applied to the active patterns AP adjacent to the gate separation pattern GS. As a result, it is possible to improve characteristics of P-channel MOSFETs including the gate electrodes GE, the source/drain regions SD, and the active patterns AP. In the case in which the MOSFET region MR is the NMOSFET region, the gate separation pattern GS may have the compressive strain, and thus the tensile strain may be applied to the active patterns AP adjacent to the gate separation pattern GS. As a result, improving characteristics of N-channel MOSFETs including the gate electrodes GE, the source/drain regions SD, and the active patterns AP may be possible.

A work function of the gate electrode GE may increase as a concentration of the impurities (e.g., oxygen or fluorine) included in the gate electrode GE increases. According to some example embodiments of the inventive concepts, a strain applied to the gate electrodes GE may be adjusted by the gate separation pattern GS adjacent to the gate electrodes GE. Thus, the amount of the impurities (e.g., oxygen or fluorine) diffused into the gate electrodes GE may be adjusted by the gate separation pattern GS. As a result, the work functions of the gate electrodes GE may be adjusted by the gate separation pattern GS adjacent to the gate electrodes GE.

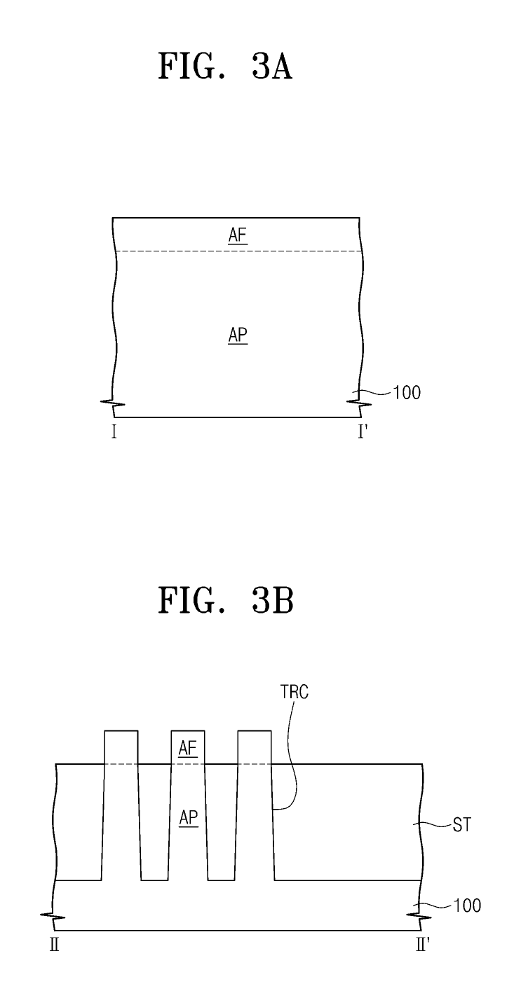

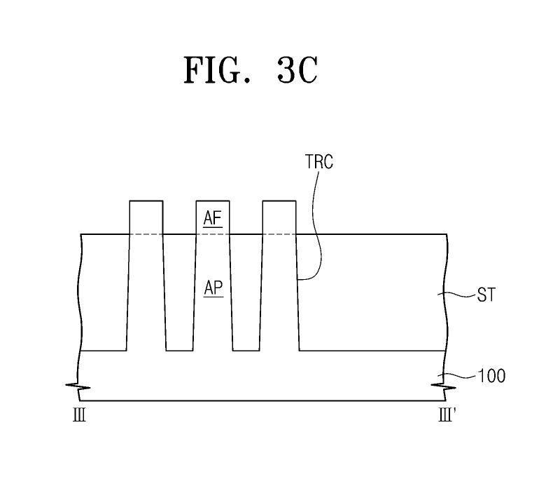

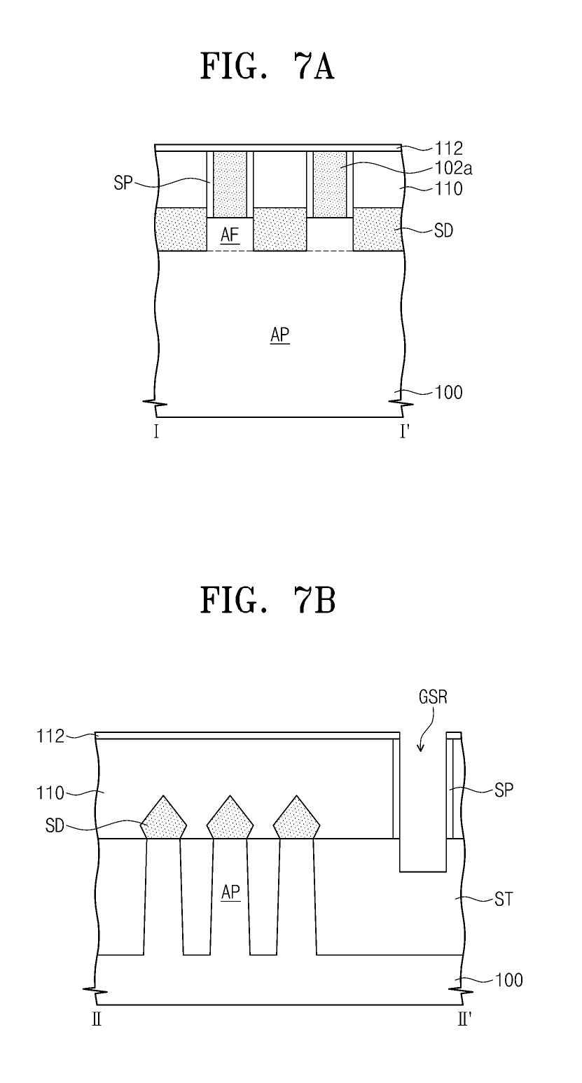

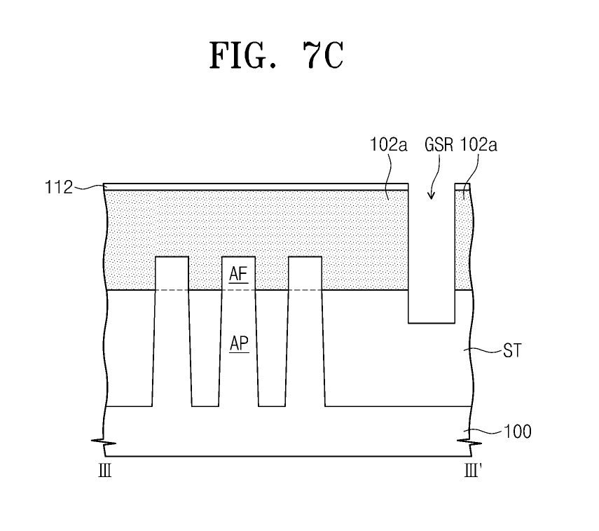

FIGS. 3A, 5A, 6A, 7A, 8A, 9A and 10A are cross-sectional views corresponding to the line I-I′ of FIG. 1 to illustrate a method for manufacturing a semiconductor device according to some example embodiments of the inventive concepts. FIGS. 3B, 5B, 6B, 7B, 8B, 9B and 10B are cross-sectional views corresponding to the line 11-11′ of FIG. 1 to illustrate a method for manufacturing a semiconductor device according to some example embodiments of the inventive concepts. FIGS. 3C, 5C, 6C, 7C, 8C, 9C and 10C are cross-sectional views corresponding to the line III-III′ of FIG. 1 to illustrate a method for manufacturing a semiconductor device according to some example embodiments of the inventive concepts. Hereinafter, the same elements as described with reference to FIGS. 1 and 2A to 2C will be indicated by the same or similar reference numerals or the same or similar reference designators, and the descriptions thereto will be omitted or mentioned briefly for the purpose of ease and convenience in explanation.

Referring to FIGS. 1, 3A, 3B, and 3C, a substrate 100 may be patterned to form a device isolation trench TRC defining a MOSFET region MR and active patterns AP. Forming the device isolation trench TRC may include forming a mask pattern (not shown) on a substrate 100, and anisotropically etching the substrate 100 using the mask pattern as an etch mask. Each of the active patterns AP may extend in the first direction D1. According to some example embodiments, the device isolation trench TRC may become progressively narrower toward a bottom surface of the device isolation trench TRC. Thus, each of the active patterns AP may become progressively narrower toward a top surface of each of the active patterns AP. The substrate 100, for example, may be a silicon substrate, a germanium substrate, or a SOI substrate.

A device isolation layer ST may be formed to fill the device isolation trench TRC. Forming the device isolation layer ST may include forming an insulating layer (e.g., a silicon oxide layer) filling the device isolation trench TRC, planarizing the insulating layer, and recessing an upper portion of the planarized insulating layer. An upper portion (i.e., an active fin AF) of each of the active patterns AP may be exposed by the recessing process.

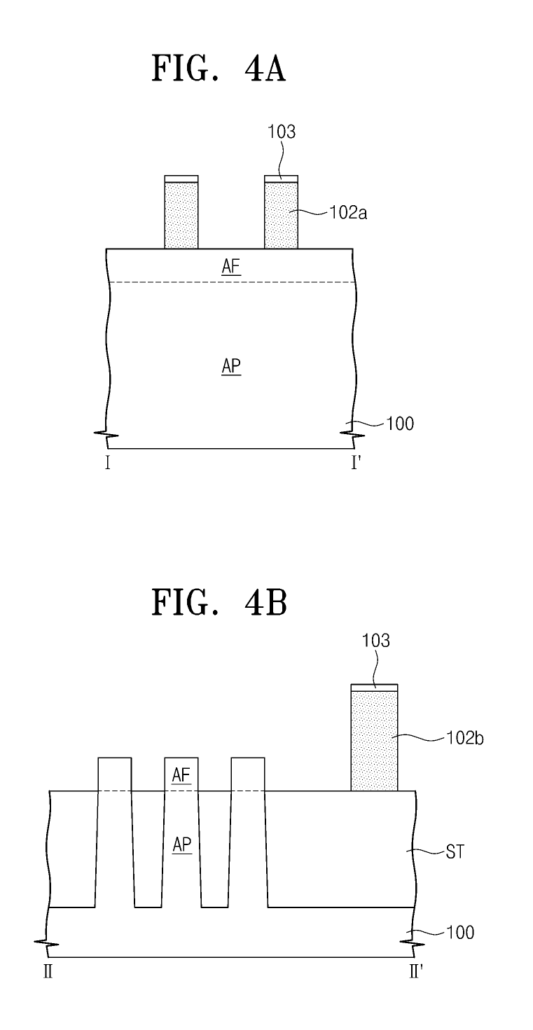

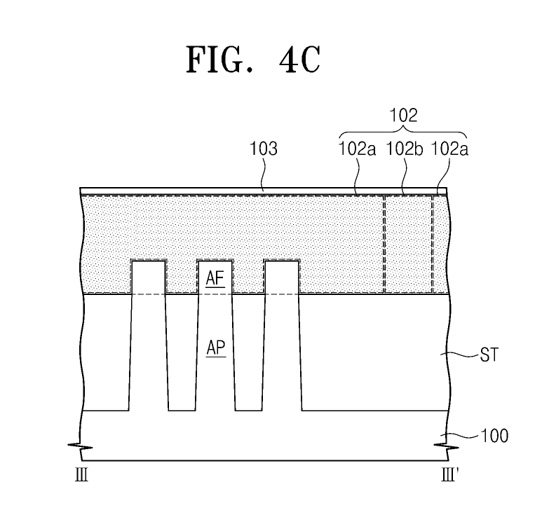

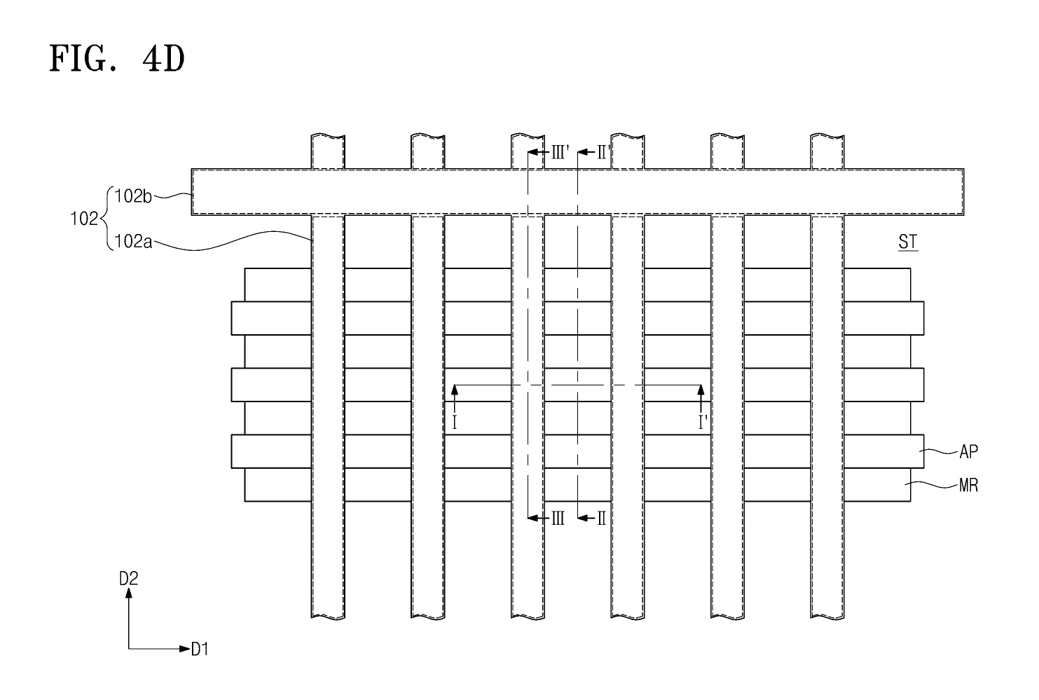

FIG. 4D is a plan view illustrating a shape of a sacrificial pattern to illustrate a method for manufacturing a semiconductor device according to some example embodiments of the inventive concepts. FIGS. 4A to 4C are cross-sectional views taken along lines I-I′, II-II′, and III-III′ of FIG. 4D, respectively.

Referring to FIGS. 4A, 4B, 4C, and 4D, a sacrificial pattern 102 may be formed on the substrate 100. The sacrificial pattern 102 may include gate portions 102a and a gate separation portion 102b. In a plan view, the gate portions 102a may correspond to the gate electrodes GE illustrated in FIG. 1 and the gate separation portion 102b may correspond to the gate separation pattern GS illustrated in FIG. 1. Each of the gate portions 102a may extend in a second direction D2 intersecting the first direction D1 to intersect the active patterns AP. The gate portions 102a may be arranged in the first direction D1. The gate separation portion 102b may divide at least one of the gate portions 102a into segments spaced apart from each other in the second direction D2. According to some example embodiments, as illustrated in FIG. 4, the gate separation portion 102b may extend in the first direction D1 to divide each of a plurality of gate portions 102a into segments spaced apart from each other in the second direction D2. Alternatively, the gate separation 102b may divide one gate portion 102a into segments spaced apart from each other in the second direction D2.

In an example embodiment, forming a sacrificial pattern 102 may include sequentially forming an etch stop layer (not shown) and a sacrificial layer (not shown) covering the active patterns AP on the substrate 100, forming a mask pattern 103 on the sacrificial layer, and patterning the sacrificial layer and the etch stop layer using the mask pattern 103 as an etch mask. Thus, an etch stop pattern (not shown) may be formed under the sacrificial pattern 102. The sacrificial pattern 102 may include, for example, poly-silicon.

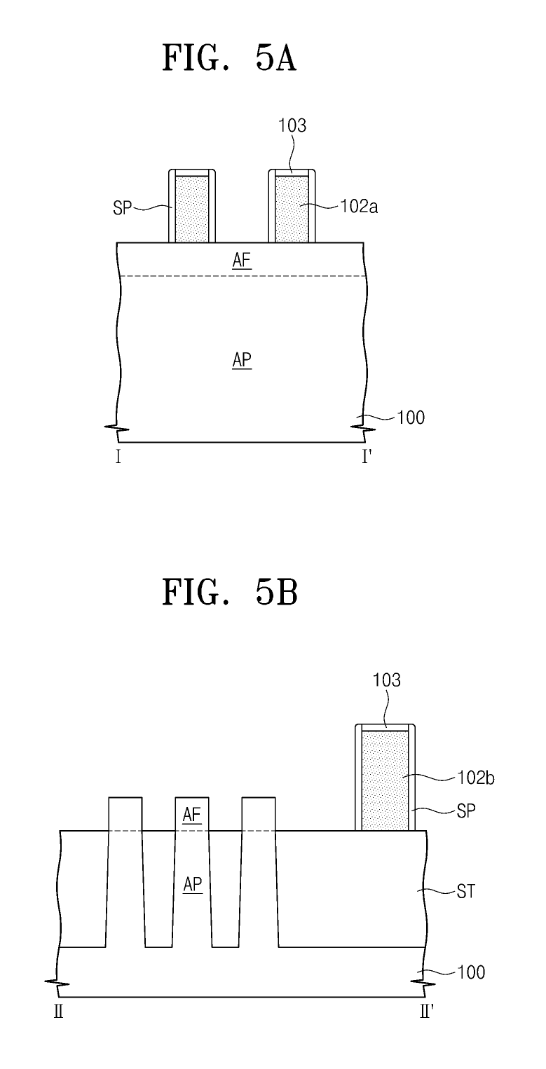

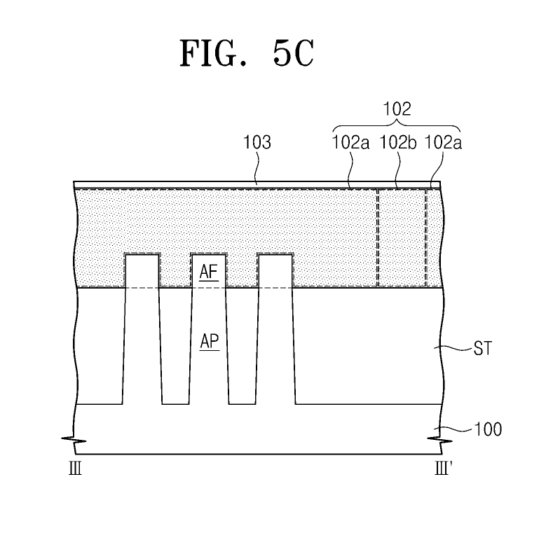

Referring to FIGS. 1, 5A, 5B, and 5C, spacers SP may be formed on sidewalls of the sacrificial pattern 102. A spacer layer (not shown) may be formed to cover the sacrificial pattern 102, and the spacer layer may be anisotropically etched to form the spacers SP. For example, the spacer may include at least one of a silicon oxide layer, a silicon nitride layer, or a silicon oxynitride layer.

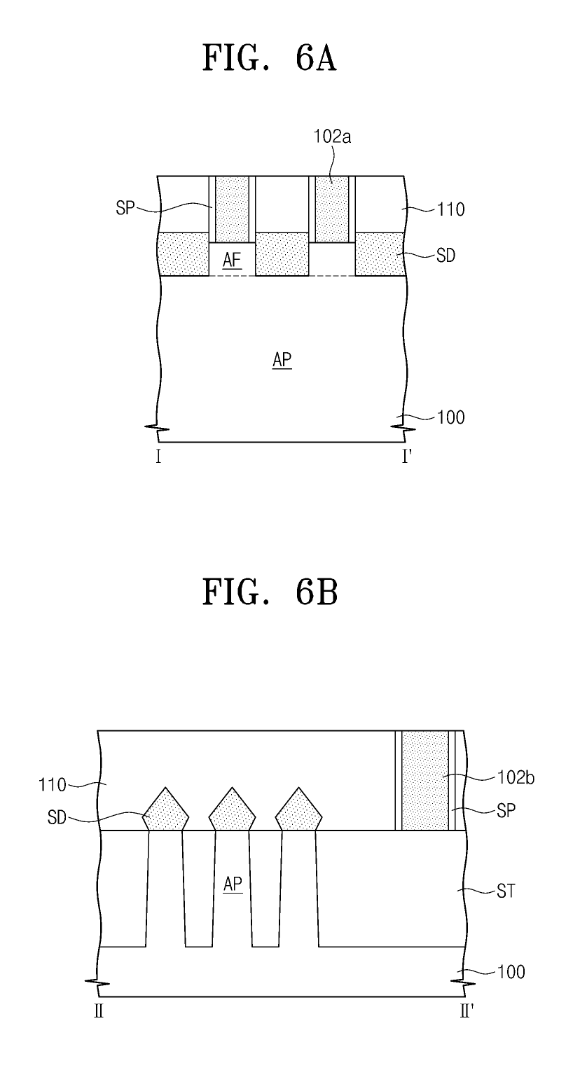

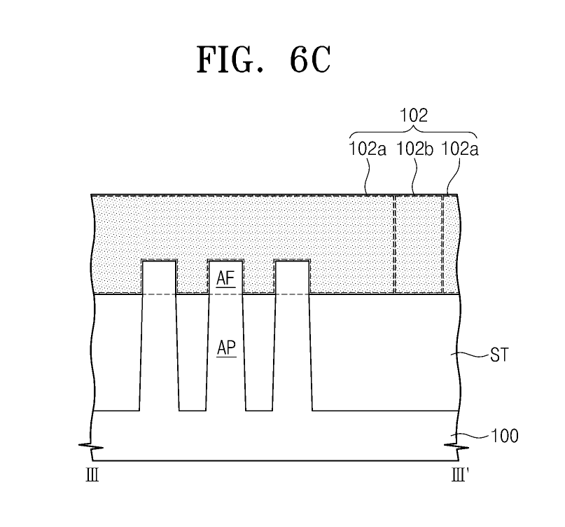

Referring to FIGS. 1, 6A, 6B, and 6C, source/drain regions SD may be formed on the active patterns AP exposed at both sides of each of the gate portions 102a of the sacrificial pattern 102.

According to some example embodiments, as illustrated in FIGS. 6A and 6B, forming the source/drain regions SD may include removing upper portions of the active patterns AP (i.e., portions of the active fins AF) disposed at both sides of each of the gate portions 102a, and performing a selective epitaxial growth (SEG) process using the active patterns AP, of which the upper portions are removed, as a seed. In the case in which the MOSFET region MR is the PMOSFET region, the source/drain regions SD may be formed to apply a compressive strain to the active patterns AP (i.e., the active fins AF) disposed under the gate portions 102a. For example, the source/drain regions SD may be formed of silicon-germanium (SiGe) doped with P-type dopants. In the case in which the MOSFET region MR is the NMOSFET region, the source/drain regions SD may be formed to apply a tensile strain to the active patterns AP (i.e., the active fins AF) disposed under the gate portions 102a. For example, the source/drain regions SD may be formed of silicon carbide (SiC) doped with N-type dopants. In some example embodiments, the source/drain regions SD may be formed of silicon (Si) doped with N-type dopants when the MOSFET region MR is the NMOSFET region.

Unlike FIGS. 6A and 6B, forming the source/drain regions SD may include performing an ion implantation process on the upper portions of the active patterns AP (i.e., the portions of the active fins AF) disposed at both sides of each of the gate portions 102a. In the case in which the MOSFET region MR is the PMOSFET region, the source/drain regions SD may be formed by implanting P-type dopant ions. In the case in which the MOSFET region MR is the NMOSFET region, the source/drain regions SD may be formed by implanting N-type dopant ions.

The source/drain regions SD may not be formed in portions of the active patterns AP (e.g., other portions of the active fins AF), which are disposed under the gate portions 102a of the sacrificial pattern 102 and overlapped with the gate portions 102a in a plan view.

A first interlayer insulating layer 110 may be formed on the substrate 100 to cover the sacrificial pattern 102. The first interlayer insulating layer 110 may include at least one of a silicon oxide layer or a silicon oxynitride layer. The first interlayer insulating layer 110 may be planarized until a top surface of the sacrificial pattern 102 is exposed.

Referring to FIGS. 1, 4D, 7A, 7B, and 7C, a gate separation recess region GSR may be formed. Forming the gate separation recess region GSR may include forming a mask pattern 112 exposing the gate separation portion 102b of the sacrificial pattern 102 on the first interlayer insulating layer 110, and etching the gate separation 102b using the mask pattern 112 as an etch mask. A portion of the device isolation layer ST may be recessed by the etching process. Thus, the gate separation recess region GSR may include the recessed region of the device isolation layer ST.

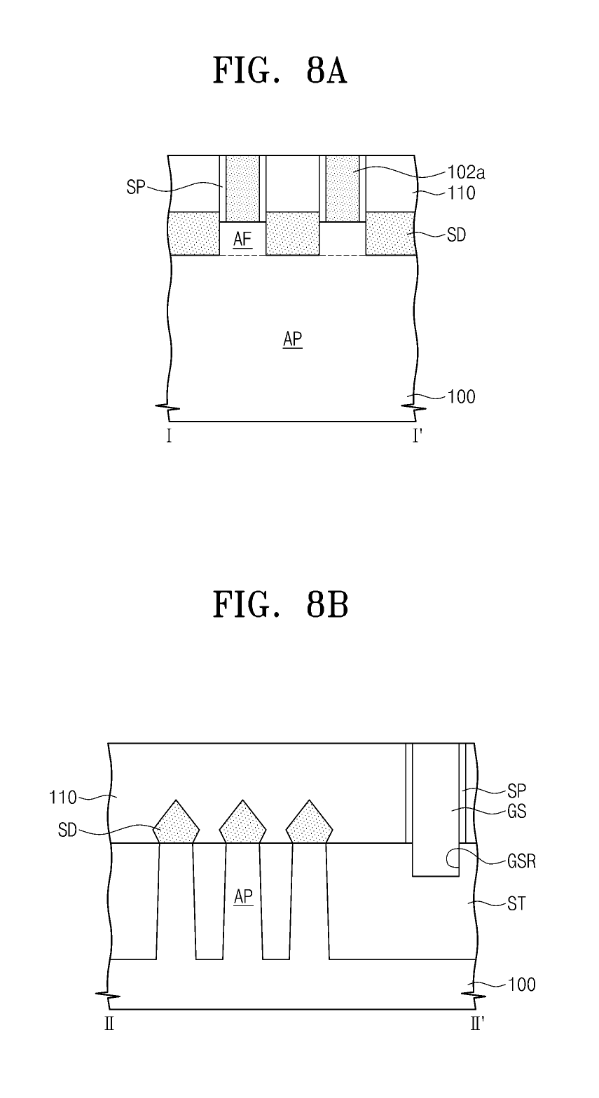

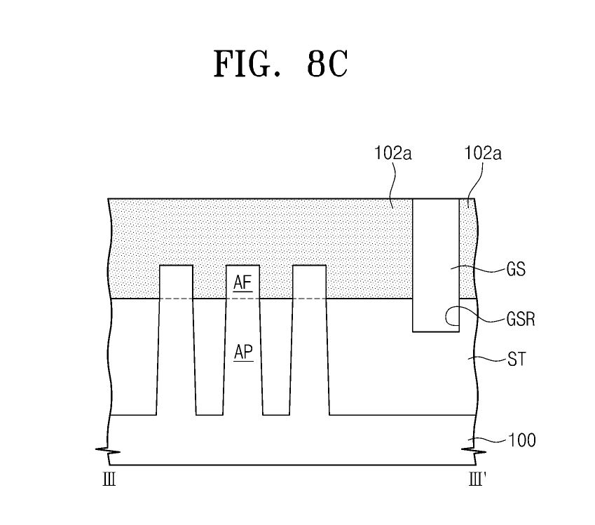

Referring to FIGS. 1, 8A, 8B, and 8C, a gate separation pattern GS may be formed. Forming the gate separation pattern GS may include forming an insulating layer (not shown) filling the gate separation recess region GSR and planarizing the insulating layer until the top surface of the first interlayer insulating layer 110 is exposed. The insulating layer for the formation of the gate separation pattern GS may be formed by, for example, a chemical vapor deposition (CVD) process, a physical vapor deposition (PVD) process, or an atomic layer deposition (ALD) process.

When the MOSFET region MR is the PMOSFET region, the insulating layer may be deposited to have relatively dense atoms. Thus, the gate separation pattern GS may include relatively dense atoms. For example, an atomic density per unit volume of the insulating layer when the MOSFET region MR is the PMOSFET region may be higher than an atomic density per unit volume of the insulating layer when the MOSFET region MR is the NMOSFET region. The gate separation pattern GS may be expanded in a subsequent thermal treatment process. Thus, the gate separation pattern GS may have a tensile strain and may apply a compressive strain to other elements (e.g., the active patterns AP) adjacent to the gate separation pattern GS. In an example embodiment, the insulating layer may include a silicon oxide layer including atoms densely formed using the ALD process.

When the MOSFET region MR is the NMOSFET region, the insulating layer may be deposited to have relatively loose atoms. Thus, the gate separation pattern GS may include relatively loose atoms. For example, the atomic density per unit volume of the insulating layer when the MOSFET region MR is the NMOSFET region may be lower than the atomic density per unit volume of the insulating layer when the MOSFET region MR is the PMOSFET region. The gate separation pattern GS may be shrunken in a subsequent thermal treatment process. Thus, the gate separation pattern GS may have a compressive strain and may apply a tensile strain to other elements (e.g., the active patterns AP) adjacent to the gate separation pattern GS. In an embodiment, the insulating layer may include a silicon nitride layer including atoms loosely formed using the CVD process.

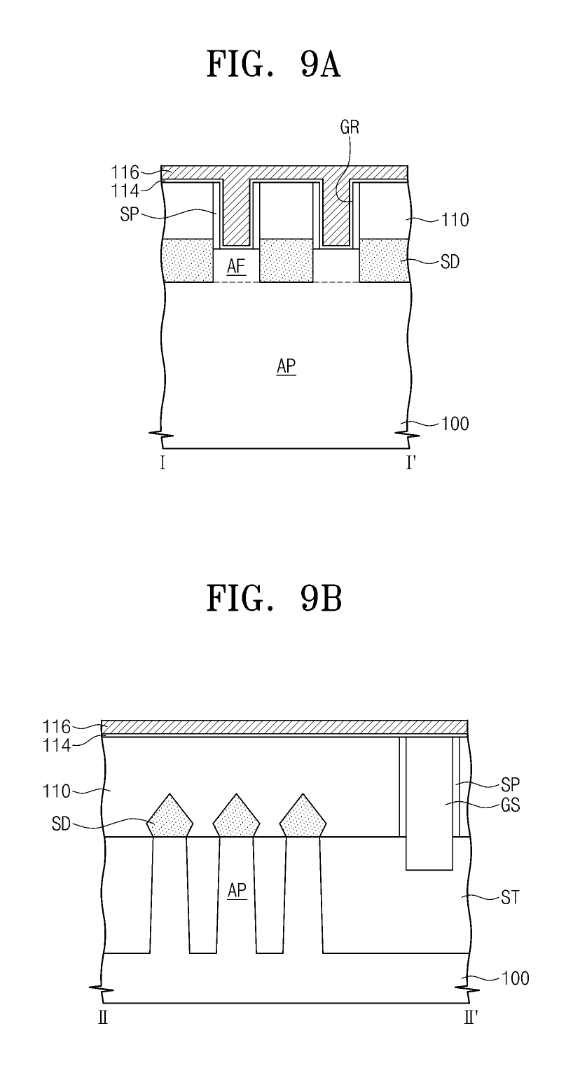

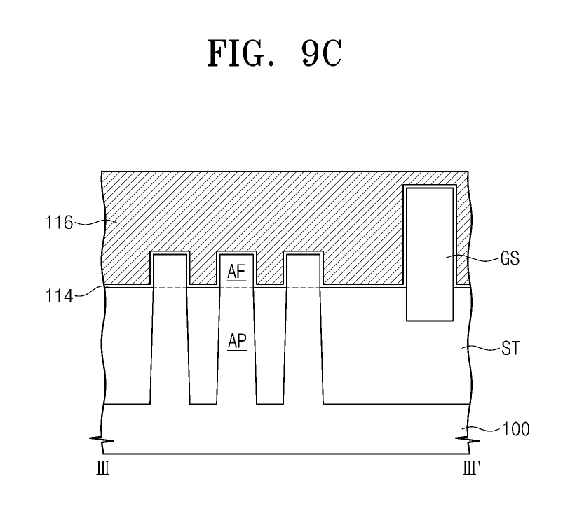

Referring to FIGS. 1, 9A, 9B, and 9C, the gate portions 102a of the sacrificial pattern 102 may be removed to form gap regions GR between the spacers SP. The gap regions GR may expose the substrate 100. Forming the gap regions 104 may include removing the gate portions 102a of the sacrificial pattern 102 by performing an etching having an etch selectivity with respect to the first interlayer insulating layer 110, the gate separation pattern GS, the spacers SP, and the etch stop pattern (not shown), and removing the etch stop pattern by performing an etching process having an etch selectivity with respect to the first interlayer insulating layer 110, the gate separation pattern GS, the spacers SP, and the substrate 100.

A gate insulating layer 114 and a gate electrode layer 116 may be sequentially formed on the substrate 100 having the gate regions GR. The gate insulating layer 114 may fill a portion of each of the gap regions GR, and the gate electrode layer 116 may fill the rest portion of each of the gap regions GR. For example, the gate insulating layer 114 may include at least one of a silicon oxide layer, a silicon oxynitride layer, or a high-k dielectric layer having a higher dielectric constant than silicon oxide. For example, the gate electrode layer 116 may include at least one of a doped semiconductor material, a metal, or a conductive metal nitride.

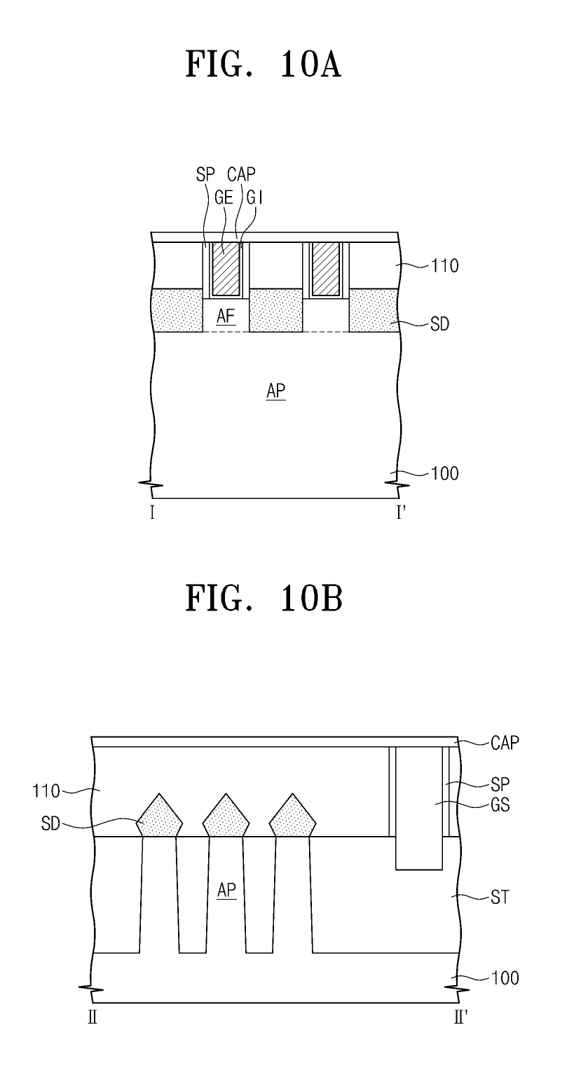

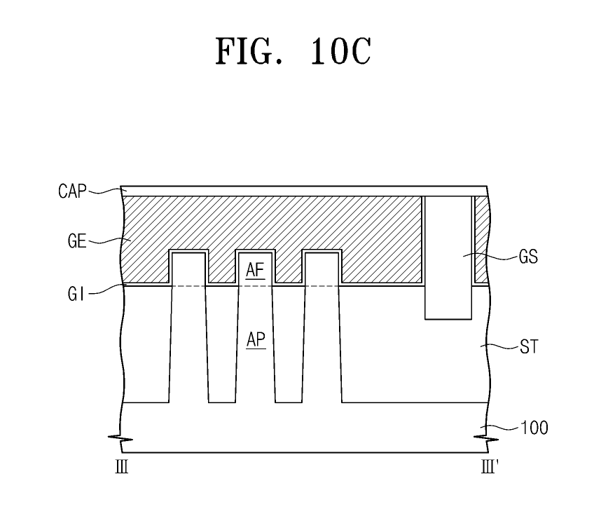

Referring to FIGS. 1, 10A, 10B, and 10C, gate insulating patterns GI and gate electrodes GE may be formed. The gate insulating patterns GI and the gate electrodes GE may be formed by planarizing the gate electrode layer 116 and the gate insulating layer 114 until the top surface of the first interlayer insulating layer 110 is exposed. Next, a capping pattern CAP may be formed to cover top surfaces of the gate electrodes GE. For example, the capping pattern CAP may include at least one of silicon oxide, silicon nitride, or silicon oxynitride.

Referring again to FIGS. 1, 2A, 2B, and 2C, a second interlayer insulating layer 120 may be formed on the capping pattern CAP. For example, the second interlayer insulating layer 120 may include at least one of a silicon oxide layer or a silicon oxynitride layer.

Next, first contacts CA and a second contact CB may be formed. The first contacts CA may penetrate the second interlayer insulating layer 120, the capping pattern CAP, and the first interlayer insulating layer 110 so as to be connected to the source/drain regions SD. The second contact CB may penetrate the second interlayer insulating layer 120 and the capping pattern CAP so as to be connected to the gate electrodes GE. For example, the first and second contacts CA and CB may include at least one of a doped semiconductor material, a metal, or a conductive metal nitride.

Interconnections (not shown) electrically connected to the first and second contacts CA and CB may be formed on the substrate 100.

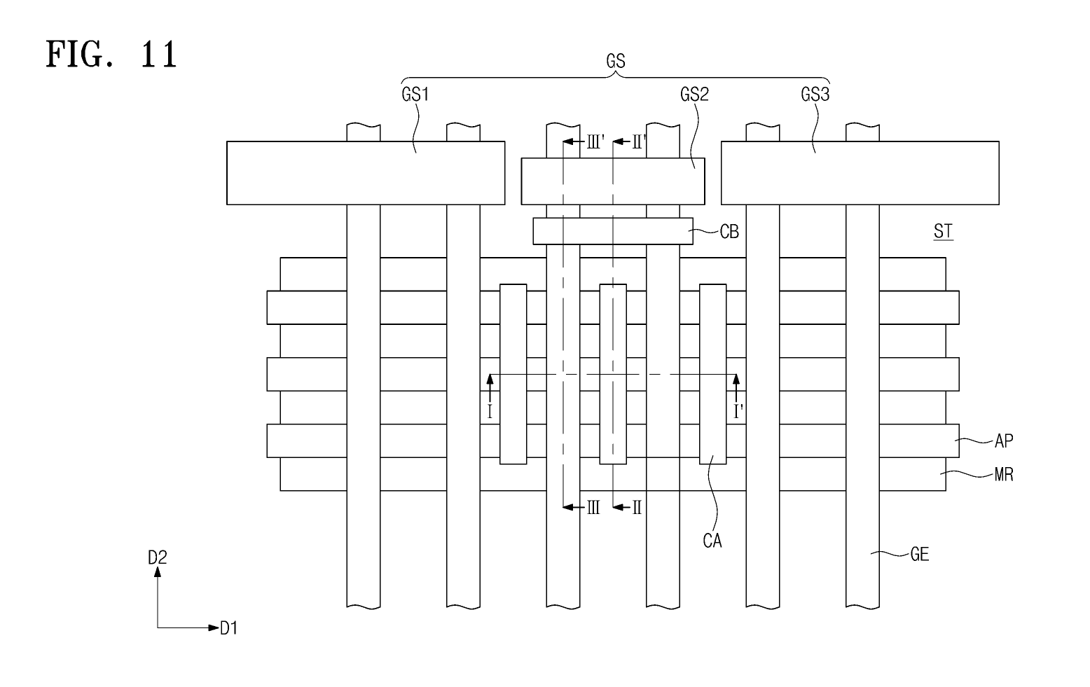

FIG. 11 is a plan view illustrating a semiconductor device according to some example embodiments of the inventive concepts. In the present embodiment, the same elements as described with reference to FIGS. 1 and 2A to 2C will be indicated by the same or similar reference numerals or the same or similar reference designators, and the descriptions thereto will be omitted or mentioned briefly for the purpose of ease and convenience in explanation.

Referring to FIG. 11, except a gate separation pattern GS, other elements of a semiconductor device of FIG. 11 may be the substantially same as corresponding elements of the semiconductor device of FIGS. 1 and 2A to 2C. Thus, the gate separation pattern GS of the semiconductor device of FIG. 11 will be described hereinafter, but the descriptions to the other elements of the semiconductor device of FIG. 11 will be omitted.

The gate separation pattern GS may include a plurality of gate separation patterns GS1, GS2, and GS3 which are spaced apart from each other and are arranged in the first direction D1. For example, as illustrated in FIG. 11, the gate separation pattern GS may include a first gate separation pattern GS1, a second gate separation pattern GS2, and a third gate separation pattern GS3.

Each of the plurality of gate separation patterns GS1, GS2, and GS3 may be the substantially same as the gate separation pattern GS described with reference to FIGS. 1 and 2A to 2C.

However, the plurality of gate separation patterns GS1, GS2, and GS3 may have strains having different magnitudes from each other and/or shapes different from each other (e.g., different widths in the first direction D1, different widths in the second direction D2, and/or different thicknesses in the direction perpendicular to the substrate 100).

As described above, since the plurality of gate separation patterns GS1, GS2, and GS3 are provided or prepared, it is possible to improve characteristics of the transistors including the gate electrodes GE, the source/drain regions, and the active patterns AP and/or to easily adjust work functions of the transistors.

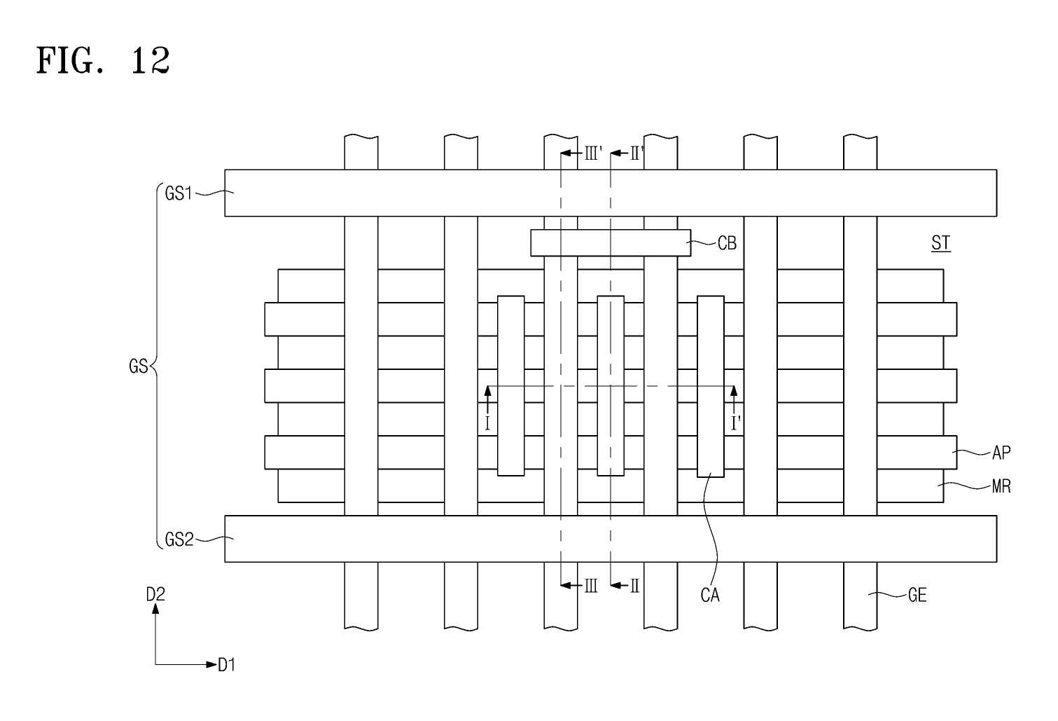

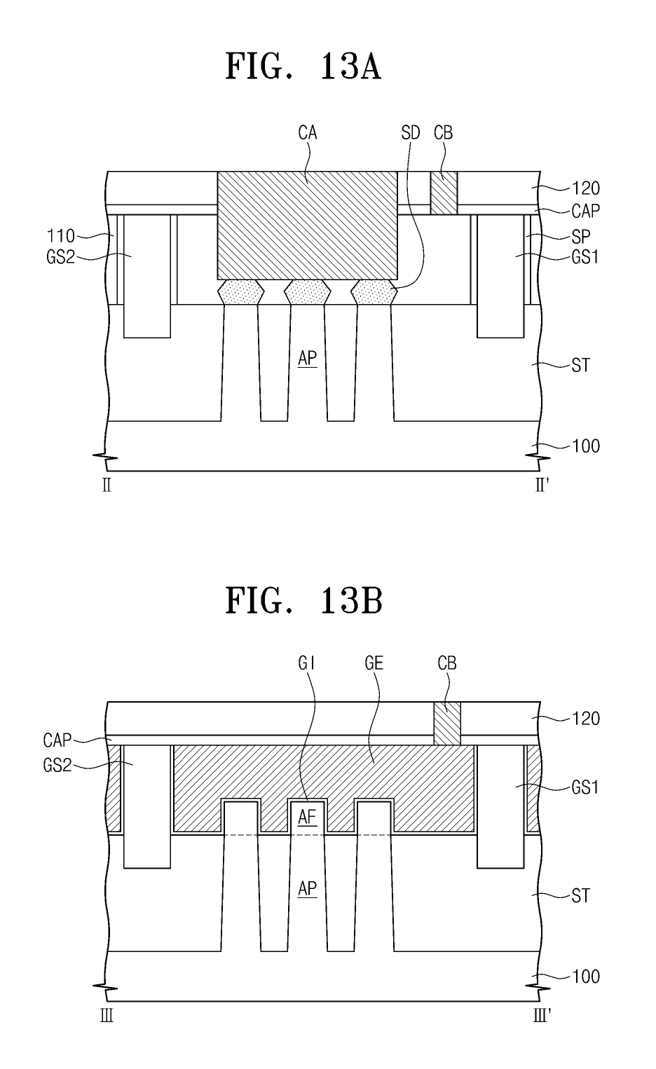

FIG. 12 is a plan view illustrating a semiconductor device according to some example embodiments of the inventive concepts. FIGS. 13A and 13B are cross-sectional views taken along lines II-II′ and III-III′ of FIG. 12, respectively. A cross-sectional view taken along a line I-I′ of FIG. 12 may be the substantially same as the cross-sectional view illustrated in FIG. 2A. In the present embodiment, the same elements as described with reference to FIGS. 1 and 2A to 2C will be indicated by the same or similar reference numerals or the same or similar reference designators, and the descriptions thereto will be omitted or mentioned briefly for the purpose of ease and convenience in explanation.

Referring to FIGS. 2A, 12, 13A, and 13B, except a gate separation pattern GS, other elements of a semiconductor device illustrated in FIGS. 2A, 12, 13A, and 13B may be the substantially same as corresponding elements of the semiconductor device illustrated in FIGS. 1 and 2A to 2C. Thus, the gate separation pattern GS of the semiconductor device illustrated in FIGS. 2A, 12, 13A, and 13B will be described hereinafter, but the descriptions to the other elements of the semiconductor device illustrated in FIGS. 2A, 12, 13A, and 13B will be omitted.

The gate separation pattern GS may include a first gate separation pattern GS1 and a second gate separation pattern GS2. Each of the first and second gate separation patterns GS1 and GS2 may be the substantially same as the gate separation pattern GS described with reference to FIGS. 1 and 2A to 2C.

Each of the first and second gate separation patterns GS1 and GS2 may be adjacent to the MOSFET region MR when viewed from a plan view. In addition, the first and second gate separation patterns GS1 and GS2 may be spaced apart from each other with the MOSFET region interposed therebetween when viewed from a plan view.

In the case in which the MOSFET region MR is the PMOSFET region, the first and second gate separation patterns GS and GS2 may have a tensile strain. Thus, a compressive strain may be applied to the active patterns AP by the first and second gate separation patterns GS1 and GS2.

In the case in which the MOSFET region MR is the NMOSFET region, the first and second gate separation patterns GS1 and GS2 may have a compressive strain. Thus, a tensile strain may be applied to the active patterns AP by the first and second gate separation patterns GS1 and GS2.

As described above, since the plurality of gate separation patterns GS1 and GS2 are adjacent to the MOSFET region MR, it is possible to improve characteristics of the transistors including the gate electrodes GE, the source/drain regions, and the active patterns AP.

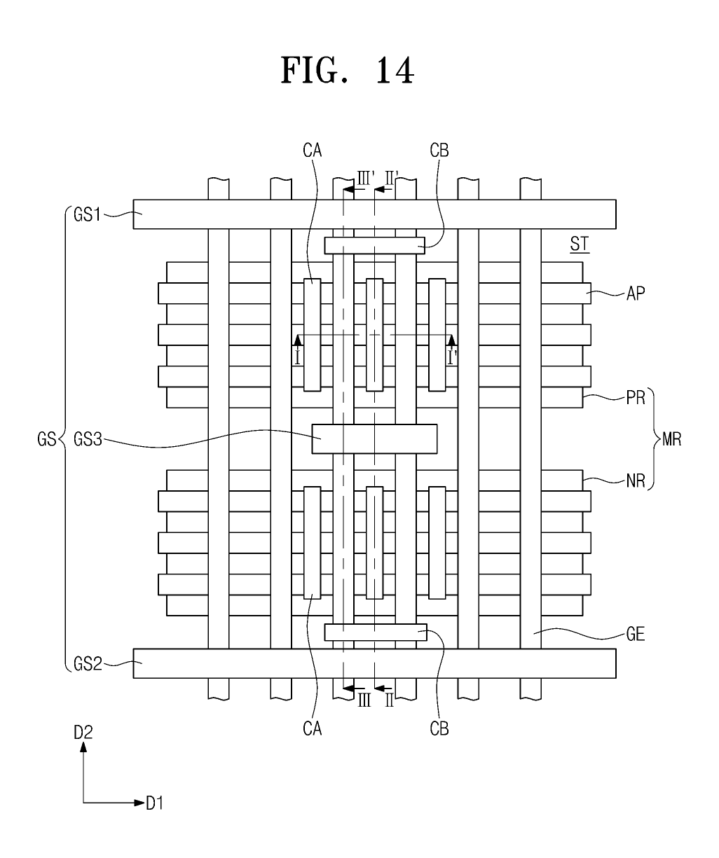

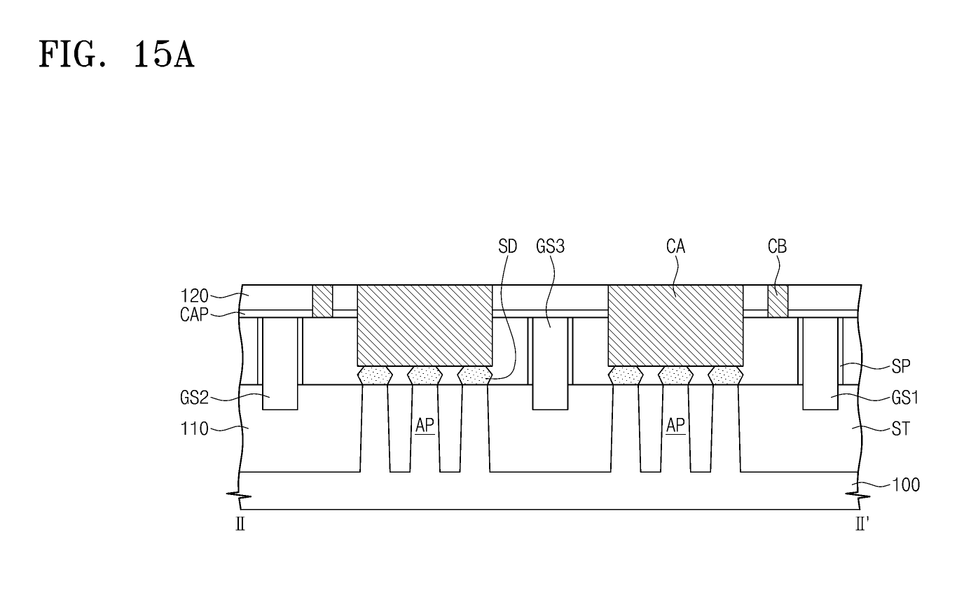

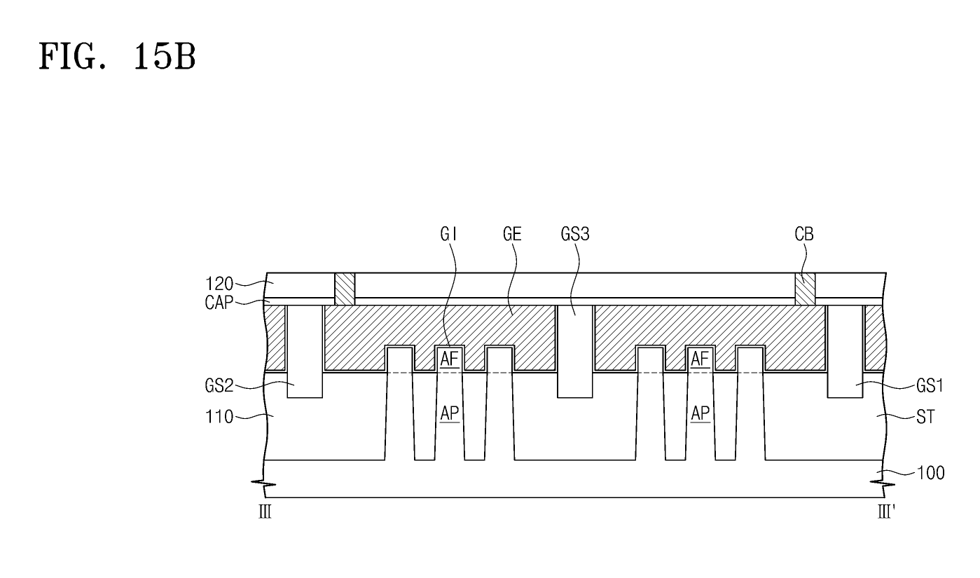

FIG. 14 is a plan view illustrating a semiconductor device according to some example embodiments of the inventive concepts. FIGS. 15A and 15B are cross-sectional views taken along lines II-II′ and III-III′ of FIG. 14, respectively. A cross-sectional view taken along a line I-I′ of FIG. 14 may be the substantially same as the cross-sectional view illustrated in FIG. 2A. In the present embodiment, the same elements as described with reference to FIGS. 1 and 2A to 2C will be indicated by the same or similar reference numerals or the same or similar reference designators, and the descriptions thereto will be omitted or mentioned briefly for the purpose of ease and convenience in explanation.

Referring to FIGS. 2A, 14, 15A, and 15B, except a MOSFET region MR and a gate separation pattern GS, other elements of a semiconductor device illustrated in FIGS. 2A, 14, 15A, and 15B may be the substantially same as corresponding elements of the semiconductor device illustrated in FIGS. 1 and 2A to 2C. Thus, the MOSFET region MR and the gate separation pattern GS of the semiconductor device illustrated in FIGS. 2A, 14, 15A, and 15B will be described hereinafter, but the descriptions to the other elements of the semiconductor device illustrated in FIGS. 2A, 14, 15A, and 15B will be omitted.

The MOSFET region MR may include a PMOSFET region PR and an NMOSFET region NR. The PMOSFET region PR and the NMOSFET region NR may be spaced apart from each other in the second direction D2. The PMOSFET region PR may be the substantially same as the MOSFET region MR of FIGS. 1 and 2A to 2C which is the PMOSFET region, and the NMOSFET region NR may be the substantially same as the MOSFET region MR of FIGS. 1 and 2A to 2C which is the NMOSFET region.

The gate separation pattern GS may include first, second, and third gate separation patterns GS1, GS2, and GS3 spaced apart from each other. Each of the first, second, and third gate separation patterns GS1, GS2, and GS3 may be the substantially same as the gate separation pattern GS described with reference to FIGS. 1 and 2A to 2C.

The first gate separation pattern GS1 and the second gate separation pattern GS2 may be spaced apart from each other with the MOSFET region MR interposed therebetween when viewed from a plan view. The first gate separation pattern GS1 may be adjacent to the PMOSFET region PR, and the second gate separation pattern GS2 may be adjacent to the NMOSFET region NR. The first gate separation pattern GS1 may have a tensile strain, and the second gate separation pattern GS2 may have a compressive strain. Thus, the first gate separation pattern GS1 may apply a compressive strain to the active patterns AP of the PMOSFET region PR, and the second gate separation pattern GS2 may apply a tensile strain to the active patterns AP of the NMOSFET region NR. As described above, the influence (e.g., the strain) of the gate separation pattern GS on other elements adjacent thereto may decrease as a distance from the gate separation pattern GS increases. Thus, the compressive strain applied to the active patterns AP of the NMOSFET region NR by the first gate separation pattern GS1 may be relatively small, and the tensile strain applied to the active patterns AP of the PMOSFET region PR by the second gate separation pattern GS2 may also be relatively small. As a result, improving characteristics of transistors formed on the PMOSFET region PR and characteristics of transistors formed on the NMOSFET region NR may be possible.

The third gate separation pattern GS3 may be provided between the PMOSFET region PR and the NMOSFET region NR when viewed from a plan view. The third gate separation pattern GS3 may have a tensile strain or a compressive strain.

According to some example embodiments, a distance between the third gate separation pattern GS3 and the PMOSFET region PR may be less than a distance between the third gate separation pattern GS3 and the NMOSFET region NR when viewed from a plan view. In this case, the third gate separation pattern GS3 may have the tensile strain. As described above, the influence (e.g., the strain) of the gate separation pattern GS on other elements adjacent thereto may decrease as a distance from the gate separation pattern GS increases. Thus, a magnitude of a compressive strain applied to the NMOSFET region NR by the third gate separation pattern GS3 may be less than that of a compressive strain applied to the PMOSFET region PR by the third gate separation pattern GS3.

According to some example embodiments, the distance between the third gate separation pattern GS3 and the NMOSFET region NR may be less than the distance between the third gate separation pattern GS3 and the PMOSFET region PR when viewed from a plan view. In this case, the third gate separation pattern GS3 may have the compressive strain.

Thus, a magnitude of a tensile strain applied to the PMOSFET region PR by the third gate separation pattern GS3 may be less than that of a tensile strain applied to the NMOSFET region NR by the third gate separation pattern GS3.

As a result, further improvement to the characteristics of the transistors formed on the PMOSFET region PR or the characteristics of the transistors formed on the NMOSFET region NR may be possible.

According to some example embodiments of the inventive concepts, the strain applied to the active pattern adjacent to the gate separation pattern may be adjusted by the gate separation pattern, and thus, improving the characteristics of the transistor adjacent to the gate separation pattern may be possible.

According to some example embodiments of the inventive concepts, the strain applied to the gate electrode adjacent to the gate separation pattern may be adjusted by the gate separation pattern, and thus, it is possible to adjust the concentration of the impurities (e.g., oxygen or fluorine) contained in the gate electrode. As a result, the work function of the gate electrode may be adjusted.

While the inventive concepts have been described with reference to example embodiments, it will be apparent to those skilled in the art that various changes and modifications may be made without departing from the spirits and scopes of the inventive concepts. Therefore, it should be understood that the above embodiments are not limiting, but illustrative. Thus, the scopes of the inventive concepts are to be determined by the broadest permissible interpretation of the following claims and their equivalents, and shall not be restricted or limited by the foregoing description.

What is claimed is:

1. A semiconductor device comprising:
a substrate including at least one metal-oxide-semiconductor field-effect transistor (MOSFET) region defined by a device isolation layer, the substrate having an active pattern extending in a first direction on the MOSFET region;
a gate electrode intersecting the active pattern on the substrate, the gate electrode extending in a second direction intersecting the first direction; and
a first gate separation pattern adjacent to the MOSFET region when viewed from a plan view, the first gate separation pattern dividing the gate electrode into segments spaced apart from each other in the second direction, the first gate separation pattern having one of a tensile strain and a compressive strain when the MOSFET region is one of a P-channel MOSFET (PMOSFET) and a N-channel MOSFET (NMOSFET), respectively.

2. The semiconductor device of claim 1, wherein
the MOSFET region is the PMOSFET region; and
the active pattern has a compressive strain.

3. The semiconductor device of claim 1, wherein
the MOSFET region is the NMOSFET region; and
the active pattern has a tensile strain.

4. The semiconductor device of claim 1, wherein a bottom surface of the first gate separation pattern is at a lower level than a bottom surface of the gate electrode.

5. The semiconductor device of claim 1, wherein
the first gate separation pattern is on the device isolation layer; and
a bottom surface of the first gate separation pattern is at a lower level than a topmost surface of the device isolation layer.

6. The semiconductor device of claim 1, wherein a top surface of the first gate separation pattern is at the same level as a top surface of the gate electrode.

7. The semiconductor device of claim 1, wherein the first gate separation pattern extends in the first direction.

8. The semiconductor device of claim 1, further comprising:
a second gate separation pattern dividing the gate electrode into segments spaced apart from each other in the second direction,
wherein the first and second gate separation patterns are spaced apart from each other with the MOSFET region therebetween and the second gate separation pattern is adjacent to the MOSFET region when viewed from a plan view, and
wherein the second gate separation pattern has a tensile strain when the MOSFET region is the PMOSFET region, and
wherein the second gate separation pattern has a compressive strain when the MOSFET region is the NMOSFET region.

9. The semiconductor device of claim 8, wherein
the MOSFET region includes a first MOSFET region and a second MOSFET region spaced apart from each other in the second direction;
the first MOSFET region corresponds to the PMOSFET region and the second MOSFET region corresponds to the NMOSFET region;
the first gate separation pattern is adjacent to the first MOSFET region and the second gate separation pattern is adjacent to the second MOSFET region; and
the first gate separation pattern has the tensile strain and the second gate separation pattern has the compressive strain.

10. The semiconductor device of claim 9, wherein
the device isolation layer extends between the first MOSFET region and the second MOSFET region, the semiconductor device further comprising:
a third gate separation pattern on the device isolation layer between the first MOSFET region and the second MOSFET region.

11. The semiconductor device of claim 10, wherein
a distance between the third gate separation pattern and the first MOSFET region is less than a distance between the third gate separation pattern and the second MOSFET region; and
the third gate separation pattern has a tensile strain.

12. The semiconductor device of claim 10, wherein
a distance between the third gate separation pattern and the second MOSFET region is less than a distance between the third gate separation pattern and the first MOSFET region; and
the third gate separation pattern has a compressive strain.

13. A semiconductor device comprising:
a substrate including at least one active pattern extending in a first direction;
a gate electrode intersecting the active pattern on the substrate, the gate electrode extending in a second direction intersecting the first direction;
source/drain regions on the active pattern at both sides of the gate electrode; and
a gate separation pattern adjacent to the active pattern when viewed from a plan view, the gate separation pattern dividing the gate electrode into segments spaced apart from each other in the second direction, and one of the active pattern and the gate separation pattern has a tensile strain and the other of the active pattern and the gate separation pattern has a compressive strain.

14. The semiconductor device of claim 13, wherein
the source/drain regions include P-type dopants;
the active pattern has the compressive strain; and
the gate separation pattern has the tensile strain.

15. The semiconductor device of claim 13, wherein
the source/drain regions include N-type dopants;
the active pattern has the tensile strain; and
the gate separation pattern has the compressive strain.

16. A semiconductor device comprising:
a substrate including at least one active pattern;
at least one gate electrode intersecting the active pattern on the substrate; and
an insulating pattern intersecting the gate electrode and adjacent to the active pattern when viewed from a plan view, one of the active pattern and the insulating pattern has a compressive strain and the other of the active pattern and the insulating pattern having a tensile strain.

17. The semiconductor device of claim 16, wherein
the active pattern has the compressive strain; and
the insulating pattern includes silicon oxide (SiO₂) and has the tensile strain.

18. The semiconductor device of claim 17, further comprising:
source/drain regions on the active pattern at both sides of the gate electrode, the source/drain regions including P-type dopants.

19. The semiconductor device of claim 16, wherein
the active pattern has the tensile strain; and
the insulating pattern includes silicon nitride (SiN) and has the compressive strain.

20. The semiconductor device of claim 19, further comprising:
source/drain regions on the active pattern at both sides of the gate electrode, the source/drain regions including N-type dopants.
